(19) United States
(12) Patent Application Publication
(10) Pub. No.: US 2024/0387722 A1
(43) Pub. Date: Nov. 21, 2024

(54) SILICON CARBIDE SPLIT-GATE MOSFETS INTEGRATING HIGH-SPEED FREEWHEELING DIODES AND PREPARATION METHODS THEREOF

(71) Applicant: NOVUS SEMICONDUCTORS CO., LTD., Chengdu (CN)

(72) Inventors: Hang GU, Chengdu (CN); Wei GAO, Chengdu (CN); Maozhou DAI, Chengdu (CN)

(73) Assignee: NOVUS SEMICONDUCTORS CO., LTD., Chengdu (CN)

(21) Appl. No.: 18/785,583

(22) Filed: Jul. 26, 2024

Related U.S. Application Data
(63) Continuation of application No. PCT/CN2022/106142, filed on Jul. 16, 2022.

(30) Foreign Application Priority Data
Jan. 26, 2022 (CN) 202210090837.4

(51) Int. Cl. H01L 29/78; H01L 27/06; H01L 29/16; H01L 29/423; H01L 29/49; H01L 29/66; H01L 29/872

(52) U.S. Cl. CPC H01L 29/7805; H01L 27/0629; H01L 29/4238; H01L 29/66712; H01L 29/872; H01L 29/1608; H01L 29/4916; H01L 29/66068

(57) ABSTRACT

SiC split-gate MOSFET integrating a high-speed freewheeling diode and a preparation method is disclosed. The MOSFET adopts split-gate design to reduce a switching loss. To avoid a problem of gate oxide reliability brought by a split-gate structure, a P-type buried layer is incorporated to reduce an electric field strength of a gate oxide layer at an edge of the polysilicon. Further, by incorporating an N-type conduction layer, a current is introduced from a trench to a drift region of the device. In addition, the high-speed freewheeling diode based on MOS structure is introduced on the other side of a cellular of the MOSFET. Relative to a conventional approach, the high-speed freewheeling diode of the present disclosure uses a surface trailing of the P-type buried layer to form a trench region, i.e., the on-site voltage drop of the high-speed freewheeling diode is minimized without increasing a number of additional photolithographic steps.

### CROSS REFERENCE TO RELATED APPLICATIONS

This application is a Continuation of International Application No. PCT/CN2022/106142 filed on Jul. 16, 2022, which claims priority to Chinese Patent Application No. 202210090837.4 filled on Jan. 26, 2022, the entire contents of which are incorporated herein by reference.

### TECHNICAL FIELD

The present disclosure relates to a technical field of power semiconductor devices, in particular, to a silicon carbide split-gate MOSFET integrating a high-speed freewheeling diode and a preparation method thereof.

### BACKGROUND

A wide-bandgap semiconductor material silicon carbide (SiC) is an ideal material for preparing a high-voltage power electronic device. Relative to a silicon material, the SiC material has advantages of a high breakdown electric field strength (4×10⁶V/cm), a high carrier saturation drift speed (2×10⁷ cm/s), a high thermal conductivity, and a good thermal stability, etc., thereby making the material especially suited for use in high-power, high-voltage, high-temperature, and radiation-resistant electronic devices.

SiC VDMOS is one of more commonly used devices in a SiC power device. Compared to bipolar devices, the SiC VDMOS has better frequency features and lower switching losses due to an absence of a charge storage effect. At the same time, a wide bandgap of the SiC material allows the SiC VDMOS to operate at a temperature as high as 300° C.

However, there are two problems with a planar SiC VDMOS. One is that a density of the junction field-effect transistor (JFET) region is great, which introduces a great Miller capacitance and increases a dynamic loss of the device; the second is that an on-state voltage drop of the parasitic SiC diode is too high, and as the parasitic SiC diode is a bipolar device with a great reverse recovery current, the parasitic SiC diode is not able to be directly used as a freewheeling diode.

Therefore, there is a need for a MOSFET body diode with a low on-state voltage drop.

### SUMMARY

One embodiment of the present disclosure provides a silicon carbide (SiC) split-gate MOSFET integrating a high-speed freewheeling diode, including a backside ohmic contact alloy, an N-doped SiC substrate, an N-doped SiC epitaxial layer, a P-doped well region, a first N-doped source region, a second N-doped source region, a P-doped source region, a first P-doped buried layer, a second P-doped buried layer, a P-doped diode trench region, a first N-doped current-conducting layer, a second N-doped current-conducting layer, a first gate oxide layer, a second gate oxide layer, a first interlayer dielectric, a second interlayer dielectric, a first polysilicon, a second polysilicon, and a source metal. The N-doped SiC substrate is located above the backside ohmic contact alloy; the N-doped SiC epitaxial layer is located above the N-doped SiC substrate; the P-doped well region is located directly above an interior of the N-doped SiC epitaxial layer; the P-doped source region is located directly above an interior of the P-doped well region; a right boundary of the first N-doped source region is in contact with a left boundary of the P-doped source region; a left boundary of the second N-doped source region is in contact with a right boundary of the P-doped source region; a right boundary of the first P-doped buried layer is in contact with a lower left boundary of the P-doped well region; a left boundary of the second P-doped buried layer is in contact with a lower right boundary of the P-doped well region; a right boundary of the P-doped diode trench region is in contact with a left boundary of the first N-doped source region; a right boundary of the first N-doped current-conducting layer is in contact with a left boundary of the P-doped diode trench region; a left boundary of the second N-doped current-conducting layer is in contact with an upper right boundary of the P-doped well region; the first gate oxide layer is located above the N-doped SiC epitaxial layer, the first N-doped current-conducting layer, the P-doped diode trench region, and the first N-doped source region; the second gate oxide layer is located above the N-doped SiC epitaxial layer, the second N-doped current-conducting layer, and the second N-doped source region; the first interlayer dielectric is located above the first gate oxide layer; the second interlayer dielectric is located above the second gate oxide layer; the first polysilicon is located below an interior of the first interlayer dielectric in contact with the first gate oxide layer and is above the first N-doped current-conducting layer, the P-doped diode trench region, and the first N-doped source region; the second polysilicon is located below an interior of the second interlayer dielectric in contact with the second gate oxide layer and is above the second N-doped current-conducting layer, the P-doped well region, the second N-doped source region; the source metal is disposed above the first interlayer dielectric, the second interlayer dielectric, the first N-doped source region, the second N-doped source region, and the P-doped source region.

In some embodiments, the doping concentration of the N-doped SiC epitaxial layer ranges from 1E15cm⁻³-1E17cm⁻³.

In some embodiments, the first P-doped buried layer is formed by aluminum ion injection, with the right boundary of the first P-doped buried layer located within a covered region of the first polysilicon, and the left boundary located outside a transverse covered region of the first polysilicon.

In some embodiments, the second P-doped buried layer is formed by aluminum ion injection, with the left boundary of the second P-doped buried layer located within a covered region of the second polysilicon, and the right boundary located outside a transverse covered region of the second polysilicon.

In some embodiments, the P-doped diode trench region is formed by injection into the same plate with the first P-doped buried layer, and a concentration of the P-doped diode trench region depends on a concentration of the first P-doped buried layer trailing to a surface.

In some embodiments, the first P-doped buried layer is formed by injection into the same plate with the second P-doped buried layer.

In some embodiments, the first N-doped current-conducting layer is formed by phosphorus ion injection, and the right boundary of the first N-doped current-conducting layer is located within a transverse region covered by the first P-doped buried layer, and the left boundary of the first N-doped current-conducting layer is located outside the transverse region covered by the first P-doped buried layer region.

In some embodiments, the second N-doped current-conducting layer is formed by over phosphorus ion injection, and the left boundary of the second N-doped current-conducting layer is located within a transverse region covered by the second P-doped buried layer, and the right boundary of the second N-doped current-conducting layer is located outside of the transverse region covered by the second P-doped buried layer.

One of the embodiments of the present disclosure further provides a method for preparing a MOSFET for a SiC split-gate MOSFET integrating a high-speed freewheeling diode as described above, comprising:

Step 1: epitaxially forming of an N-doped SiC epitaxial layer on an N-type SiC substrate;

Step 2: forming a first barrier layer on a surface of the N-doped SiC epitaxial layer by chemical vapor deposition, lithographing the first barrier layer to form the first ion-injection window, and forming a P-doped well region by adopting a high-temperature aluminum ion injection; and an ambient temperature of the high-temperature aluminum ion injection is greater than 773 K;

Step 3: forming a second barrier layer on the first barrier layer and a surface of the P-doped well region by chemical vapor precipitation, forming a second ion-injection window by a sidewall of the second barrier layer left by etching, and forming a first N- doped source region and a second N-doped source region by adopting a high-temperature phosphorus ion injection; and an ambient temperature of the high-temperature phosphorus ion injection injection is greater than 773 K;

Step 4: removing the first barrier layer and the second barrier layer, forming a third barrier layer on a surface of the N-doped SiC epitaxial layer by chemical vapor precipitation, and forming a third ion-injection window by photolithography, and form a P-doped source region by adopting a high-temperature aluminum ion injection; and the ambient temperature of the high-temperature phosphorus ion injection is greater than 773 K;

Step 5: removing the third barrier layer; forming a fourth barrier layer by chemical vapor deposition, forming a fourth ion-injection window by photolithography, and forming a first P-doped buried layer and a second P-doped buried layer by adopting a high-temperature aluminum ion injection, and surface trailing concentrations of the first P-doped buried layer and the second P-doped buried layer form a P-doped diode trench region; and the ambient temperature of the high-temperature aluminum ion injection is greater than 773 K;

Step 6: removing the fourth barrier layer; forming a fifth barrier layer using chemical vapor deposition, forming a fifth ion-injection window using photolithography, forming a first N-doped current-conducting layer and a second N-doped current-conducting layer by adopting a high-temperature aluminum ion injection, and expanding a width of the first N-doped source region; and the ambient temperature of the high-temperature aluminum ion injection is greater than 773 K;

Step 7: removing the fifth barrier layer and performing a high-temperature annealing; a temperature of the high-temperature annealing being in a range of 1600° C.˜1800° C.; forming a gate oxide layer using a thermal oxygen oxidation and annealing, and then forming a polysilicon by deposition; forming a first polysilicon and a second polysilicon by photolithography, forming an interlayer dielectric by chemical vapor deposition, and forming a first gate oxide layer, a second gate oxide layer, a first interlayer dielectric, and a second interlayer dielectric photolithography; and

Step 8: precipitating a nickel alloy and performing a rapid thermal annealing to form an ohmic contact, forming a source metal by sputtering aluminum metal, and forming a backside ohmic contact alloy.

### BRIEF DESCRIPTION OF THE DRAWINGS

The present disclosure is further described in terms of exemplary embodiments, which is described in detail with reference to the drawings. These embodiments are not limiting, and in these embodiments, the same reference numerals in the various drawings represent similar structures, and wherein:

FIG. 1 is a schematic diagram illustrating a structure of a SiC split-gate MOSFET integrating a high-speed freewheeling diode according to some embodiments of the present disclosure;

FIG. 2 is a schematic diagram illustrating an equivalent circuit of a SiC split-gate MOSFET integrating a high-speed freewheeling diode according to some embodiments of the present disclosure;

FIG. 3 is a schematic diagram illustrating a forward conduction current path of a SiC split-gate MOSFET integrating a high-speed freewheeling diode according to some embodiments of the present disclosure;

FIG. 4 is a schematic diagram illustrating a reverse continuation current path of a SiC split-gate MOSFET integrating a high-speed freewheeling diode according to some embodiments of the present disclosure;

FIG. 5-FIG. 12 are schematic structural diagrams obtained after a completion of the various process steps in a method of preparing a SiC split-gate MOSFET integrating a high-speed freewheeling diode according to some embodiments of the present disclosure.

In figures: 1—backside ohmic contact alloy, 2—N-doped SiC substrate, 3—N-doped SiC epitaxial layer, 4—P-doped well region, 51—first N-doped source region, 52—second N-doped source region, 6—P-doped source region, 71—first P-doped buried layer, 72—second P-doped buried layer, 8—P-doped diode trench region, 91—first N-doped current- conducting layer, 92—second N-doped current-conducting layer, 101—first gate oxide layer, 102—second gate oxide layer, 111—first interlayer dielectric, 112—second interlayer dielectric, 121—first polysilicon, 122—second polysilicon, 13—source metal; 21—first barrier layer, 1-1—first ion-injection window, 22—second barrier layer, 1-2—second ion-injection window, 31—third barrier layer, 1-3—third ion-injection window, 41—fourth barrier layer, 1-4—fourth ion-injection window, 61—fifth barrier layer, 1-5—fifth ion-injection window.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios according to these drawings without creative labor. Unless obviously obtained from the context or the context illustrates otherwise, the same numeral in the drawings refers to the same structure or operation.

It should be understood that the terms “system,” “device,” “unit,” and/or “module” as used herein are ways to distinguish between different components, elements, parts, sections, or assemblies at different levels. However, words may be replaced by other expressions if other words accomplish the same purpose.

As shown in the present disclosure and in the claims, unless the context clearly suggests an exception, the words “one,” “a,” “an,” and/or the” do not refer specifically to the singular, but may also include the plural. Generally, the terms “including” and “comprising” suggest only the inclusion of explicitly identified steps and elements that do not constitute an exclusive list, and the method or apparatus may also include other steps or elements.

Flowcharts are used in the present disclosure to illustrate operations performed by a system in accordance with embodiments of the present disclosure. It should be appreciated that the preceding or following operations are not necessarily performed in an exact sequence. Instead, steps may be processed in reverse order or simultaneously. Also, it is possible to add other operations to these processes or to remove a step or steps from these processes.

To address problems of the existing planar SiC VDMOS, the present disclosure provides a SiC split-gate MOSFET integrating a high-speed freewheeling diode, which adopts a split-gate structure and shields a polysilicon edge electric field by a P-type buried layer, thereby ensuring a long-term reliability of the device while sufficiently reducing a Miller capacitance. In addition, in the present disclosure, a high-speed freewheeling diode is integrated on the other side of the MOSFET. The diode is formed using a diode connection manner of the split-gate MOSFET (i.e., source-drain shorted). In the present disclosure, by regulating an injected dosage of the P-type buried layer, an on-state voltage drop is conveniently adjusted, thereby substantially reducing the on-state voltage drop of the MOSFET body diode. Furthermore, the diode is a unipolar device with no reverse recovery current, allowing for quick turn-on and off, which significantly reduces a turn-off dynamic loss.

### Embodiment 1

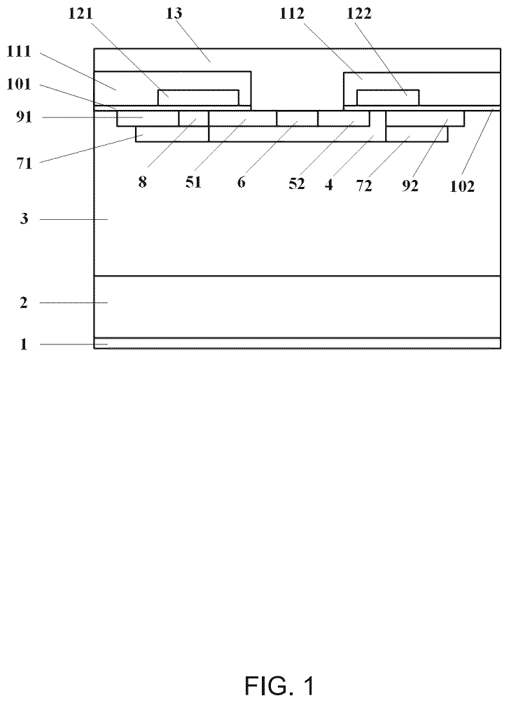

As shown in FIG. 1, some embodiments of the present disclosure provide a SiC split-gate MOSFET integrating a high-speed freewheeling diode, comprising a backside ohmic contact alloy (1), an N-doped SiC substrate (2), an N-doped SiC epitaxial layer (3), a P-doped well region (4), a first N-doped source region (51), a second N-doped source region (52), a P-doped source region (6), a first P-doped buried layer (71), a second P-doped buried layer (72), a P-doped diode trench region (8), a first N-doped current-conducting layer (91), a second N-doped current-conducting layer (92), a first gate oxide layer (101), a second gate oxide layer (102), a first interlayer dielectric (111), a second interlayer dielectric (112), a first polysilicon (121), a second polysilicon (122), and a source metal (13).

The N-doped SiC substrate (2) is located above the backside ohmic contact alloy (1); the N-doped SiC epitaxial layer (3) is located above the N-doped SiC substrate (2); the P-doped well region (4) is located directly above an interior of the N-doped SiC epitaxial layer (3); and the P-doped source region (6) is located directly above an interior of the P-doped well region (4).

A right boundary of the first N-doped source region (51) is in contact with a left boundary of the P-doped source region (6); a left boundary of the second N-doped source region (52) is in contact with a right boundary of the P-doped source region (6); a right boundary of the first P-doped buried layer (71) is in contact with a lower left boundary of the P-doped well region (4); a left boundary of the second P-doped buried layer (72) is in contact with a lower right boundary of the P-doped well region (4); a right boundary of the P-doped diode trench region (8) is in contact with a left boundary of the first N-doped source region (51); a right boundary of the first N-doped current-conducting layer (91) is in contact with a left boundary of the P-doped diode trench region (8); and a left boundary of the second N-doped current-conducting layer (92) is in contact with an upper right boundary of the P-doped well region (4).

The first gate oxide layer (101) is located above the N-doped SiC epitaxial layer (3), the first N-doped current-conducting layer (91), the P-doped diode trench region (8), and the first N-doped source region (51); the second gate oxide layer (102) is located above the N-doped SiC epitaxial layer (3), the second N-doped current-conducting layer (92), and the second N-doped source region (52); the first interlayer dielectric (111) is located above the first gate oxide layer (101); the second interlayer dielectric (112) is located above the second gate oxide layer (102); the first polysilicon (121) is located below an interior of the first interlayer dielectric (111) in contact with the first gate oxide layer (101) and is above the first N-doped current-conducting layer (91), the P-doped diode trench region (8), and the first N-doped source region (51); the second polysilicon (122) is located below an interior of the second interlayer dielectric (112) in contact with the second gate oxide layer (102) and is above the second N-doped current-conducting layer (92), the P-doped well region (4), and the second N-doped source region (52); and the source metal (13) is disposed above the first interlayer dielectric (111), the second interlayer dielectric (112), the first N-doped source region (51), the second N-doped source region (52), and the P-doped source region (6).

In some embodiments, a doping concentration of the N-doped SiC epitaxial layer (3) ranges from 1E15cm⁻³-1E17cm⁻³. Exemplarily, the doping concentration may be 1E16 cm⁻³. In some embodiments, the doping concentration of the N-doped SiC epitaxial layer (3) may also range from 1E14cm⁻³-1E18cm⁻³.

In some embodiments, the first P-doped buried layer (71) is formed by aluminum ion injection, with the right boundary of the first P-doped buried layer (71) located within a covered region of the first polysilicon (121), and the left boundary located outside a transverse covered region of the first polysilicon (121). In some embodiments, the first P-doped buried layer (71) may also be formed by B (boron) ion injection.

In some embodiments, the second P-doped buried layer (72) is formed by aluminum ion injection, with the left boundary of the second P-doped buried layer (72) located within a covered region of the second polysilicon (122), and the right boundary located outside a transverse covered region of the second polysilicon (122).

In some embodiments, the P-doped diode trench region (8) is formed by injection into the same plate with the first P-doped buried layer (71), and a concentration of the P-doped diode trench region (8) depends on a concentration of the first P-doped buried layer (71) trailing to a surface, that is, the concentration of the P-doped diode trench region (8) is determined by Gaussian distribution trailing of the first P-doped buried layer (71) formed by ion injection. The injection in the same plate refers to that the P-doped diode trench region (8) and the first P-doped buried layer (71) are obtained by exposure development using the same mask plate.

As the first P-doped buried layer (71) is formed by ion injection, and a concentration distribution of the ion injection in a longitudinal direction is similar to the Gaussian distribution, the P-doped diode trench region (8) is actually a surface concentration of the first P-doped buried layer (71). Therefore, only a peak concentration of the first P-doped buried layer (71) needs to be controlled to control the concentration of the P-doped diode trench region (8). In some embodiments, the peak concentration of the first P-doped buried layer (71) may range from 1E17to 1E19 cm⁻³, such as 1E18 cm⁻³, and the concentration of the P-doped diode trench region (8) may range from 1E15to 1E17 cm⁻³, such as 1E16 cm⁻³.

In some embodiments, the first P-doped buried layer (71) is formed by injection into the same plate with the second P-doped buried layer (72).

As a depth of the first N-doped current-conducting layer (91) is shallow and has a great influence on properties such as an electric field strength of the gate oxide layer, an injection distribution of the first N-doped current-conducting layer (91) needs to be carefully controlled. Therefore, in some embodiments, the first N-doped current-conducting layer (91) is formed by phosphorus P (P) ion injection, with the right boundary of the first N-doped current-conducting layer (91) located within the transverse region covered by the first P-doped buried layer (71), and the left boundary located outside the transverse region covered by the first P-doped buried layer (71). In some embodiments, the first N-doped current-conducting layer (91) may also be formed by nitrogen (N) ion injection.

In some embodiments, the second N-doped current-conducting layer (92) is formed by P ion injection, with the left boundary of the second N-doped current-conducting layer (92) located within the transverse region covered by the second P-doped buried layer (72), and the right boundary located outside the transverse region covered by the second P-doped buried layer (72).

In some embodiments, the first polysilicon (121) is shorted to the source metal (13) in the plate. The plate is the mask plate designed for lithography based on a device design, a performance requirement, and a process level.

In some embodiments, as the MOSFET integrates the high-speed freewheeling diode, which operates on a principle that the first polysilicon (121) is equipotential to a source. When the device is in a third quadrant operating state, the first polysilicon (121) is positively biased with respect to the source, causing one side of the P-doped diode trench region (8) close to the oxide layer to form an inverse-type layer trench, and thus an integrated high-speed freewheeling diode conducts. In order to realize the function, in some embodiments, a design in which the plate is shorted to the source metal (13) is used, i.e., a hole needs to be punched at the first polysilicon (121) and covered with the source metal (13) to make the source metal (13) and the first polysilicon (121) shorted.

In some embodiments of the present disclosure, a SiC split-gate MOSFET integrating a high-speed freewheeling diode possess beneficial effects at least including:

(1) the optimized separation gate structure (corresponding to the first polysilicon (121) and the second polysilicon (122) in FIG. 1) is used to sufficiently reduce the Miller capacitance of the device, thereby reducing the switching loss of the device. Furthermore, in order to protect the gate oxide layer of the split-gate, a P-type buried layer (corresponding to the first P-doped buried layer (71) and the second P-doped buried layer (72) in FIG. 1) is used to weaken an edge electric field of the gate oxide layer, thereby improving a long-term reliability of the device;

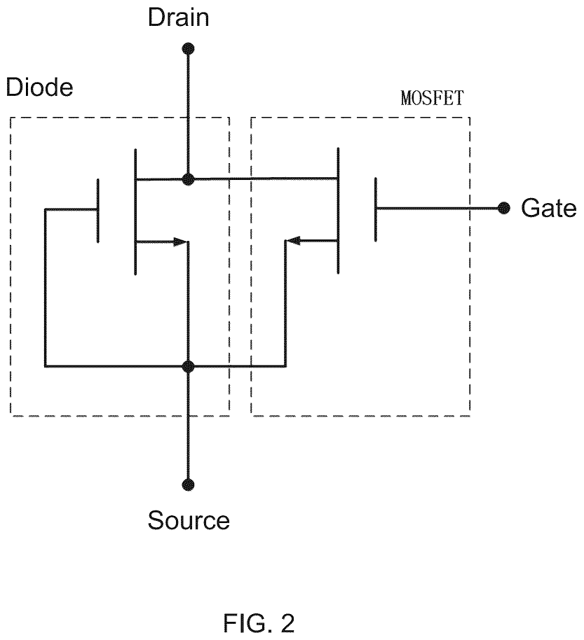

(2) Another trench different from the MOSFET trench is formed with the P-type buried layer on the other side of a cellular (e.g., corresponding to the P-doped diode trench region (8) in FIG. 1), which is characterized by a low threshold voltage. Based on this, a rectifier based on a diode connection of the MOSFET (i.e., a dashed box region on a left side in FIG. 2) is fabricated using the trench. Compared to a traditional MOSFET diode, the rectifier has advantages of a reduced on-state voltage and a unipolar conduction (no reverse recovery current, no bipolar degradation), enabling the rectifier to be used as the freewheeling diode for the MOSFET, and drastically reducing a dynamic loss;

(3) The MOSFET provided in the present disclosure integrates the high-speed freewheeling diode, which uses a common JFET region and a termination region, thereby sufficiently improving utilization efficiency of the device region and lowering a system cost; and

(4) the integration of the MOSFET with the high-speed freewheeling diode allows a chip area to be enlarged (greater than a single MOSFET or a single diode), making the device withstand a greater power during an overcurrent, thus improving a robustness of the device.

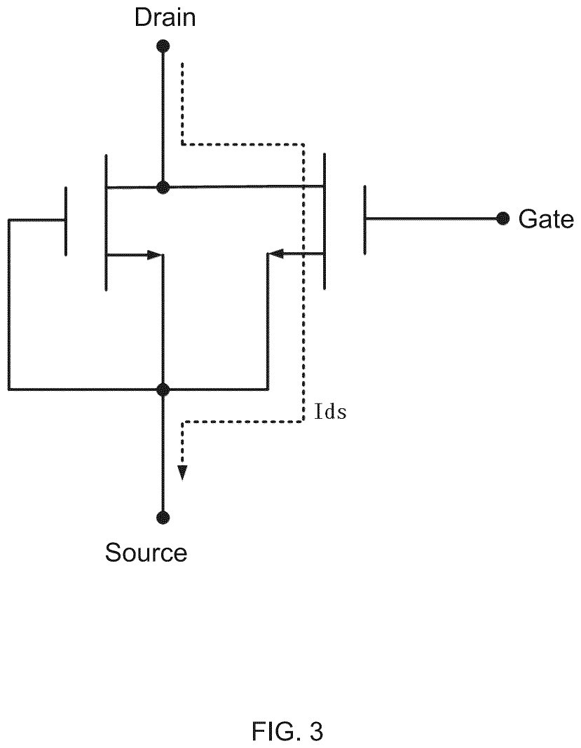

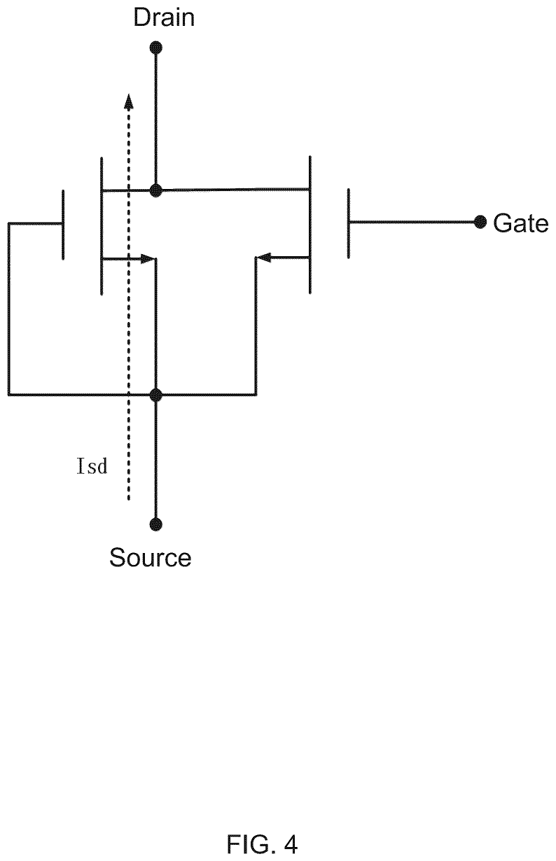

In some embodiments of the present disclosure, an equivalent circuit diagram of a SiC split-gate MOSFET integrating a high-speed freewheeling diode is shown in FIG. 2. When the device is operating normally, a gate in the MOSFET region in FIG. 2 is applied with a forward bias voltage, and the trench opens; as shown in FIG. 3, electrons flow from the source to the drain under an action of the electric field, thereby forming a current Ids from the drain to the source; as shown in FIG. 4, when the device is turned off and enters the third quadrant operating state, a positive potential difference from the source to the drain causes the diode region to conduct, forming a current Isd from the source to the drain.

### Embodiment 2

Some embodiments of the present disclosure also provide a method for preparing a SiC split-gate MOSFET (e.g., the MOSFET shown in Embodiment 1) integrating a high-speed freewheeling diode. The method includes the following steps.

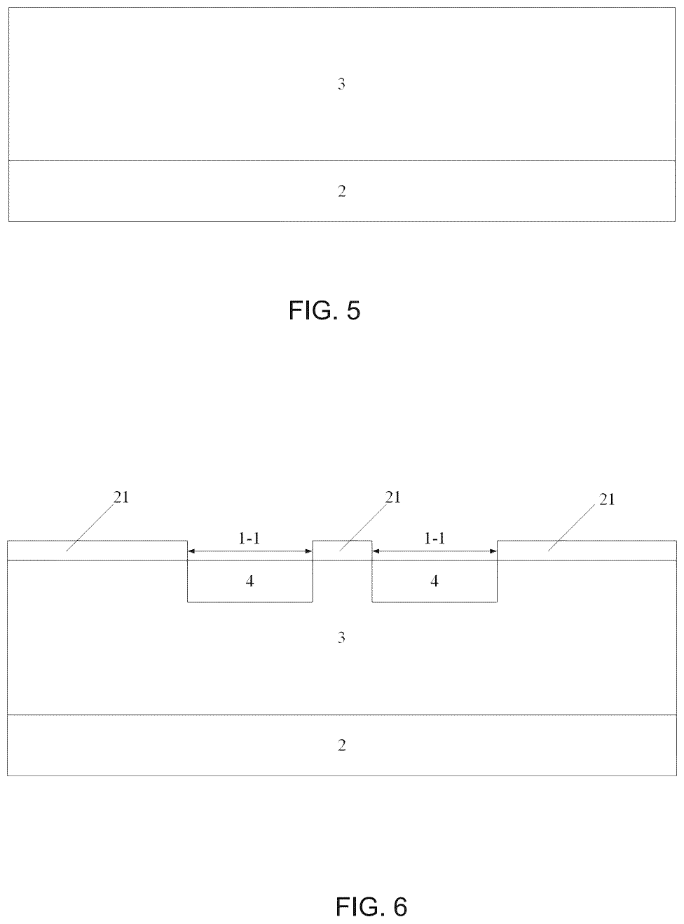

Step 1: epitaxially forming an N-doped SiC epitaxial layer (3) on an N-type SiC substrate (2) and obtaining a structure shown in FIG. 5.

Step 2: forming a first barrier layer (21) on a surface of the N-doped SiC epitaxial layer (3) by chemical vapor deposition, lithographing the first barrier layer (21) to form a first ion-injection window (1-1), and forming a P-doped well region (4) by adopting a high-temperature aluminum ion injection; and obtaining the structure shown in FIG. 6. The high-temperature refers to that an ambient temperature of the aluminum ion injection is greater than 773 K.

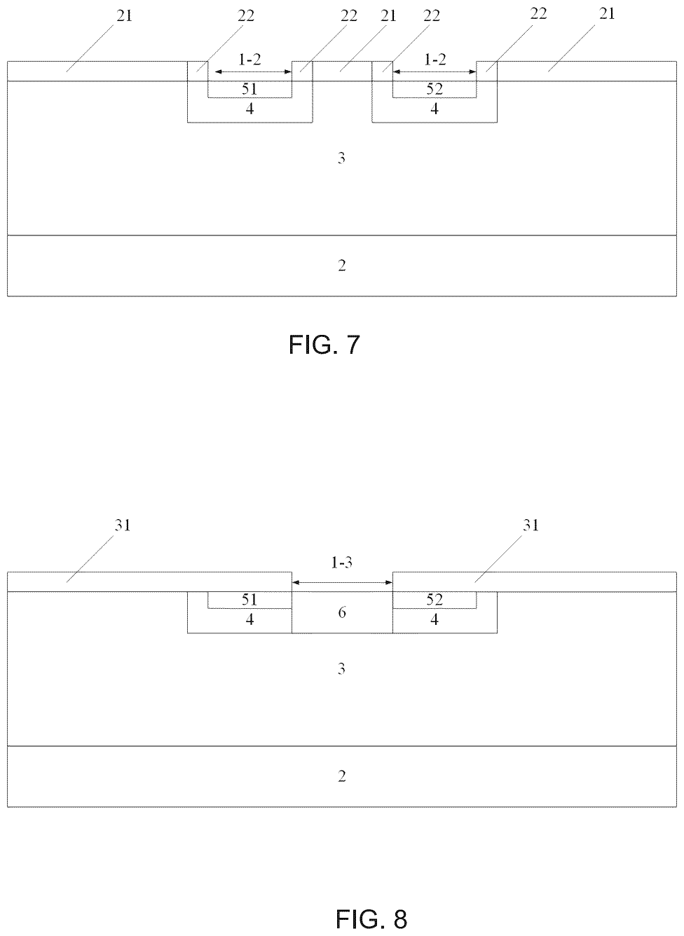

Step 3: forming a second barrier layer (22) on the first barrier layer (21) and a surface of the P-doped well region (4) by chemical vapor precipitation, forming a second ion-injection window (1-2) by a side wall of the second barrier layer (22) left by etching, and forming a first N-doped source region (51) and a second N-doped source region (52) by adopting a high-temperature phosphorus ion injection; and obtaining the structure shown in FIG. 7. The high temperature refers to that an ambient temperature of the phosphorus ion injection is greater than 773 K.

Step 4: removing the first barrier layer (21) and the second barrier layer (22), forming a third barrier layer (31) on a surface of the N-doped SiC epitaxial layer (3) by chemical vapor precipitation, and forming a third ion-injection window (1-3) by photolithography, and forming a P-doped source region (6) by adopting a high-temperature aluminum ion injection; and obtaining the structure shown in FIG. 8. The high temperature refers to that the ambient temperature of the aluminum ion injection is greater than 773 K.

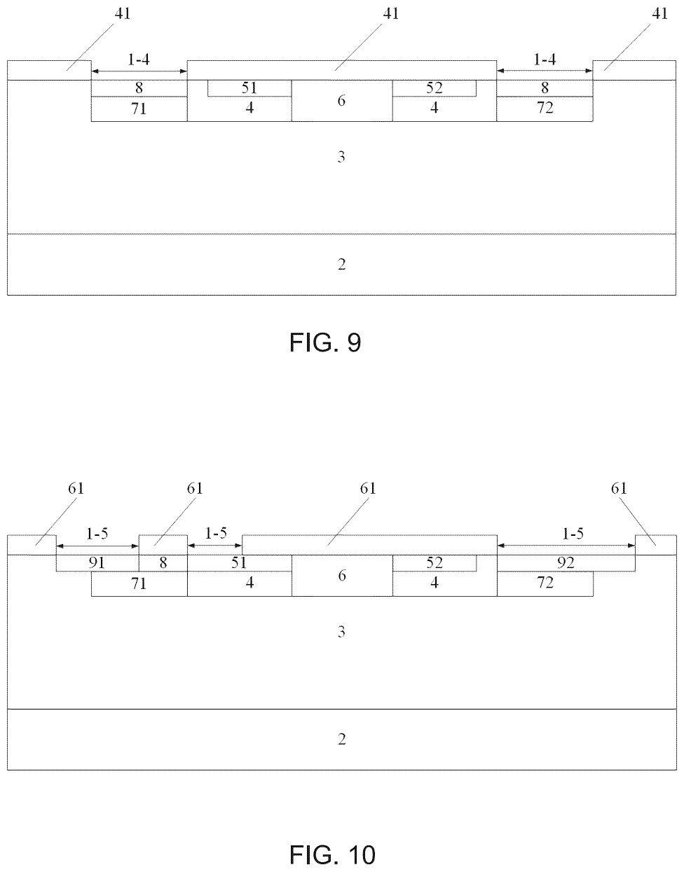

Step 5: removing the third barrier layer (31); forming a fourth barrier layer (41) by chemical vapor deposition, forming a fourth ion-injection window (1-4) by photolithography, and forming a first P-doped buried layer (71) and a second P-doped buried layer (72) by adopting a high-temperature aluminum ion injection, and the surface trailing concentrations of the first P-doped buried layer (71) and the second P-doped buried layer (72) form a P-doped diode trench region (8); and obtaining the structure shown in FIG. 9; the high temperature refers to that the ambient temperature of aluminum ion injection is greater than 773 K.

Step 6: removing the fourth barrier layer (41); forming a fifth barrier layer (61) using chemical vapor deposition, forming a fifth ion-injection window (1-5) using photolithography, forming a first N-doped current-conducting layer (91) and a second N-doped current-conducting layer (92) by adopting a high-temperature P ion injection, and expanding a width of the first N-doped source region (51); and obtaining the structure shown in FIG. 10. The ambient temperature of the high-temperature aluminum ion injection is greater than 773 K.

Step 7: removing the fifth barrier layer (61) and performing a high temperature annealing. A temperature of the high-temperature annealing is in range of 1600° C. to 1800° C.; for example, the temperature of the high-temperature annealing may be 1660° C. In some embodiments, the temperature of the high-temperature annealing may be 1200°° C. to 2000° C.

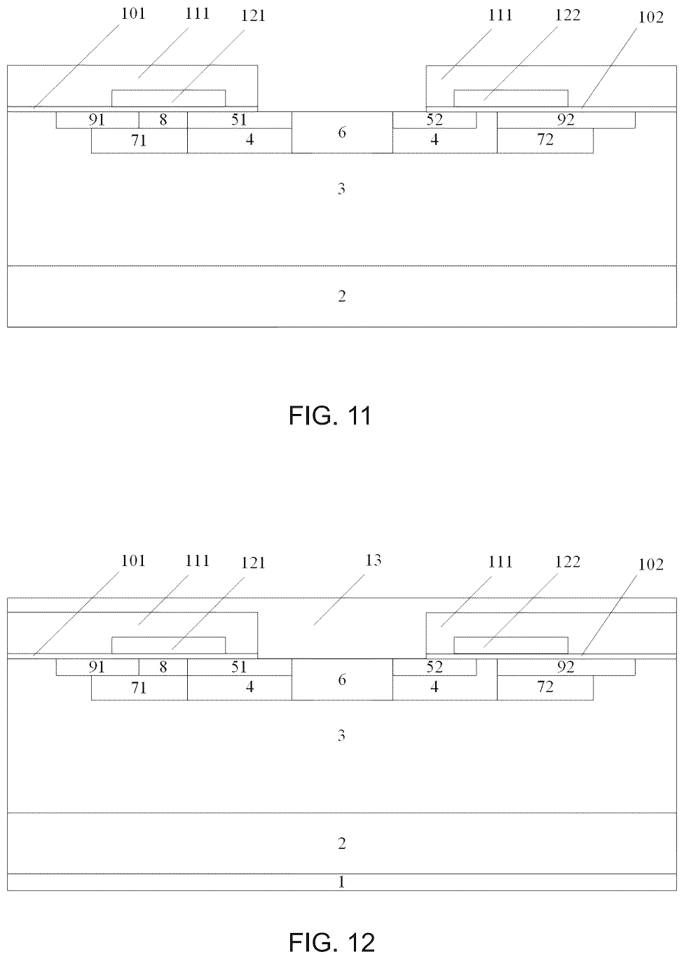

Forming a gate oxide layer using a thermal oxygen oxidation and annealing, and then forming a polysilicon by deposition; forming a first polysilicon (121) and a second polysilicon (122) by photolithography, forming an interlayer dielectric by chemical vapor deposition, and forming a first gate oxide layer (101), a second gate oxide layer (102), a first interlayer dielectric (111) photolithography, and a second interlayer dielectric (112); and obtaining the structure shown in FIG. 11.

Step 8: precipitating a nickel alloy and performing a rapid thermal annealing to form an ohmic contact, forming a source metal (13) by sputtering an aluminum metal, and forming a backside ohmic contact alloy (1), and obtaining the structure shown in FIG. 12.

It should be noted that the foregoing description of steps 1 to 8 is for the purpose of exemplification and illustration only, and does not limit the scope of application of the present disclosure. For those skilled in the art, various corrections and changes may be made to steps 1 to steps 8 under the guidance of the present disclosure. However, these corrections and changes remain within the scope of the present disclosure.

The method for preparing a SiC split-gate MOSFET integrating the high-speed freewheeling diode in some embodiments of the present disclosure possesses beneficial at least effects including:

The other trench different from the MOSFET trench (e.g., the P-doped diode trench region (8) in FIGS. 9-12) is formed with a P-type buried layer on the other side of the cellular, which is characterized by a low threshold voltage. On this basis, the rectifier based on the MOSFET diode connection is prepared using the trench. Compared to a body diode of a tradition MOSFET, the rectifier has advantages of a reduced on-state voltage and a unipolar conduction (no reverse recovery current, no bipolar degradation). In this way, the rectifier may be used as a freewheeling diode for MOSFET, which dramatically reduces a dynamic loss.

The basic concepts have been described above, and it is apparent to those skilled in the art that the foregoing detailed disclosure serves only as an example and does not constitute a limitation of the present disclosure. While not expressly stated herein, those skilled in the art may make various modifications, improvements, and amendments to the present disclosure. Those types of modifications, improvements, and amendments are suggested in the present disclosure, so these types of modifications, improvements, and amendments remain within the spirit and scope of the exemplary embodiments of the present disclosure.

Also, the present disclosure uses specific words to describe embodiments of the present disclosure. Such as “an embodiment,” “an embodiment,” and/or “some embodiments” means a feature, structure, or characteristic associated with at least one embodiment of the present disclosure. Accordingly, it should be emphasized and noted that “one embodiment” or “an embodiment” or “an alternative embodiment” referred two or more times in different locations in the present disclosure do not necessarily refer to the same embodiment. In addition, certain features, structures, or characteristics in one or more embodiments of the present disclosure may be suitably combined.

In addition, unless expressly stated in the claims, the order of the processing elements and sequences, the use of numerical letters, or the use of other names as described in the present disclosure are not intended to limit the order of the processes and methods of the present disclosure. While some embodiments of the invention that are currently considered useful are discussed in the foregoing disclosure by way of various examples, it should be appreciated that such details serve only illustrative purposes, and that additional claims are not limited to the disclosed embodiments, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that in order to simplify the presentation of the disclosure of the present disclosure, and thereby aid in the understanding of one or more embodiments of the invention, the foregoing descriptions of embodiments of the present disclosure sometimes group multiple features together in a single embodiment, accompanying drawings, or in a description thereof. However, this method of disclosure does not imply that the objects of the present disclosure require more features than those mentioned in the claims. Rather, claimed subject matter may lie in less than all features of a single foregoing disclosed embodiment.

Finally, it should be understood that the embodiments described in the present disclosure are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A silicon carbide (SiC) split-gate MOSFET integrating a high-speed freewheeling diode, including a backside ohmic contact alloy, an N-doped SiC substrate, an N-doped SiC epitaxial layer, a P-doped well region, a first N-doped source region, a second N-doped source region, a P-doped source region, a first P-doped buried layer, a second P-doped buried layer, a P-doped diode trench region, a first N-doped current-conducting layer, a second N-doped current-conducting layer, a first gate oxide layer, a second gate oxide layer, a first interlayer dielectric, a second interlayer dielectric, a first polysilicon, a second polysilicon, and a source metal; wherein
the N-doped SiC substrate is located above the backside ohmic contact alloy; the N-doped SiC epitaxial layer is located above the N-doped SiC substrate; the P-doped well region is located directly above an interior of the N-doped SiC epitaxial layer; the P-doped source region is located directly above an interior of the P-doped well region; a right boundary of the first N-doped source region is in contact with a left boundary of the P-doped source region; a left boundary of the second N-doped source region is in contact with a right boundary of the P-doped source region; a right boundary of the first P-doped buried layer is in contact with a lower left boundary of the P-doped well region; a left boundary of the second P-doped buried layer is in contact with a lower right boundary of the P-doped well region; a right boundary of the P-doped diode trench region is in contact with a left boundary of the first N-doped source region; a right boundary of the first N-doped current-conducting layer is in contact with a left boundary of the P-doped diode trench region; a left boundary of the second N-doped current-conducting layer is in contact with an upper right boundary of the P-doped well region; the first gate oxide layer is located above the N-doped SiC epitaxial layer, the first N-doped current-conducting layer, the P-doped diode trench region, and the first N-doped source region; the second gate oxide layer is located above the N-doped SiC epitaxial layer, the second N-doped current-conducting layer, and the second N-doped source region; the first interlayer dielectric is located above the first gate oxide layer; the second interlayer dielectric is located above the second gate oxide layer; the first polysilicon is located below an interior of the first interlayer dielectric in contact with the first gate oxide layer and is above the first N-doped current-conducting layer, the P-doped diode trench region, and the first N-doped source region; the second polysilicon is located below an interior of the second interlayer dielectric in contact with the second gate oxide layer and is above the second N-doped current-conducting layer, the P-doped well region, the second N-doped source region; the source metal is disposed above the first interlayer dielectric, the second interlayer dielectric, the first N-doped source region, the second N-doped source region, and the P-doped source region.

2. The SiC split-gate MOSFET integrating the high-speed freewheeling diode of claim 1, wherein:
a doping concentration of the N-doped SiC epitaxial layer ranges from 1E15cm⁻³-1E17cm⁻³.

3. The SiC split-gate MOSFET integrating the high-speed freewheeling diode of claim 1, wherein:
the first P-doped buried layer is formed by aluminum ion injection, the right boundary of the first P-doped buried layer is located within a covered region of the first polysilicon, and the left boundary of the first P-doped buried layer is located outside a transverse covered region of the first polysilicon.

4. The SiC split-gate MOSFET integrating the high-speed freewheeling diode of claim 1, wherein:
the second P-doped buried layer is formed by aluminum ion injection, with the left boundary of the second P-doped buried layer located within a covered region of the second polysilicon, and the right boundary located outside a transverse covered region of the second polysilicon.

5. The SiC split-gate MOSFET integrating the high-speed freewheeling diode of claim 1, wherein:
the P-doped diode trench region is formed by injection into a same plate with the first P-doped buried layer, and a concentration of the P-doped diode trench region depends on a concentration of the first P-doped buried layer trailing to a surface.

6. The SiC split-gate MOSFET integrating the high-speed freewheeling diode according to claim 1, wherein:
the first P-doped buried layer is formed by injection into a same plate with the second P-doped buried layer.

7. The SiC split-gate MOSFET integrating the high-speed freewheeling diode according to claim 1, wherein:
the first N-doped current-conducting layer is formed by phosphorus ion injection, the right boundary of the first N-doped current-conducting layer is located within a transverse region covered by the first P-doped buried layer, and the left boundary of the first N-doped current-conducting layer is located outside the transverse region covered by the first P-doped buried layer region.

8. The SiC split-gate MOSFET integrating the high-speed freewheeling diode according to claim 1, wherein:
the second N-doped current-conducting layer is formed by phosphorus ion injection, and the left boundary of the second N-doped current-conducting layer is located within a transverse region covered by the second P-doped buried layer, and the right boundary of the second N-doped current-conducting layer is located outside of the transverse region covered by the second P-doped buried layer.

9. The SiC split-gate MOSFET integrating the high-speed freewheeling diode according to claim 1, wherein:
the first polysilicon is shorted to the source metal in the plate.

10. A method for preparing a MOSFET for a silicon carbide (SiC) split-gate MOSFET integrating a high-speed freewheeling diode according to claim 1, comprising:
step 1: epitaxially forming an N-doped SiC epitaxial layer on an N-type SiC substrate;
step 2: forming a first barrier layer on a surface of the N-doped SiC epitaxial layer by chemical vapor deposition, lithographing the first barrier layer to form a first ion-injection window, and form a P-doped well region by adopting a high-temperature aluminum ion injection; wherein an ambient temperature of the high-temperature aluminum ion injection is greater than 773K;
step 3: forming a second barrier layer on the first barrier layer and a surface of the P-doped well region by chemical vapor precipitation, forming a second ion-injection window by a side wall of the second barrier layer left by etching, and forming a first N-doped source region and a second N-doped source region by adopting a high-temperature phosphorus ion injection; wherein an ambient temperature of the high-temperature phosphorus ion injection is greater than 773K;
step 4: removing the first barrier layer and the second barrier layer, forming a third barrier layer on a surface of the N-doped SiC epitaxial layer by chemical vapor precipitation, and forming a third ion-injection window by photolithography, and form a P-doped source region by adopting the high temperature aluminum ion injection;
wherein the ambient temperature of the high-temperature phosphorus ion injection is greater than 773 K;
step 5: removing the third barrier layer; forming a fourth barrier layer by chemical vapor deposition, forming a fourth ion-injection window by photolithography, and form a first P-doped buried layer and a second P-doped buried layer by adopting the high-temperature aluminum ion injection, wherein surface trailing concentrations of the first P-doped buried layer and the second P-doped buried layer form a P-doped diode trench region; and the ambient temperature of the high-temperature aluminum ion injection is greater than 773 K;
step 6: removing the fourth barrier layer; forming a fifth barrier layer using chemical vapor deposition, forming a fifth ion-injection window using photolithography, form a first N-doped current-conducting layer and a second N-doped current-conducting layer by adopting the high-temperature aluminum ion injection, and expanding a width of the first N-doped source region; wherein the ambient temperature of the high-temperature aluminum ion injection is greater than 773 K;
step 7: removing the fifth barrier layer and performing a high-temperature annealing; wherein a temperature of the high-temperature annealing is in a range of 1600°° C.˜1800° C.; forming a gate oxide layer using thermal oxygen oxidation and annealing, then forming a polysilicon by deposition; forming a first polysilicon and a second polysilicon by photolithography, forming an interlayer dielectric by chemical vapor deposition, and forming a first gate oxide layer, a second gate oxide layer, a first interlayer dielectric, and a second interlayer dielectric photolithography; and
step 8: depositing a nickel alloy and performing rapid thermal annealing to form an ohmic contact, forming a source metal by sputtering aluminum metal, and forming a backside ohmic contact alloy.
